(19) United States
(12) Patent Application Publication
(10) Pub. No.: US 2026/0093886 A1
(43) Pub. Date: Apr. 2, 2026

(54) MODELING AND VERIFICATION OF CIRCUIT WITH DUAL-EDGE CLOCKED LOGIC

(71) Applicant: International Business Machines Corporation, Armonk, NY (US)

(72) Inventors: Robert Lowell Kanzelman, Rochester, NY (US); Justin Wang, Austin, TX (US); Ali S. El-Zein, Austin, TX (US); Viresh Paruthi, Austin, TX (US)

(21) Appl. No.: 18/898,773

(22) Filed: Sep. 27, 2024

(51) Int. Cl. G06F 30/3323; G06F 30/323; G06F 30/3312

(52) U.S. Cl. CPC G06F 30/3323; G06F 30/323; G06F 30/3312

(57) ABSTRACT

An example operation may include one or more of receiving a logical model of a circuit written in a hardware description language (HDL), the logical model of the circuit comprising normalized and ratioed clocks, and simulation-efficient edge-triggered latches or flip-flops, translating the logical model of the circuit into a physical model of the circuit in the HDL via a software application, wherein the translating comprises replacing the normalized and ratioed clocks in the logical model of the circuit with a base system clock, divider logic generating hold waveforms to achieve ratioed behavior, and pulse-enabled latches, and replacing the edge-triggered latches or flip-flops with pulse-generation logic and pulse-enabled latches, executing a formal verification which determines whether the logical model of the circuit is functionally equivalent to the physical model of the circuit, and displaying results of the formal verification via a graphical user interface (GUI) of the software application.

### BACKGROUND

A coded design of a device (e.g., an integrated circuit, etc.) may be written in a hardware design language (HDL) and may implement synchronous clocking using a system clock distributed by a mesh or other tree-based clock structure. The system clock may be used to enable capturing of data into a state-holding pair of latches (flip-flop) at a particular edge of the system clock (typically falling edge). Alternatively, edge detection circuitry may generate a pulse at a particular edge of the system clock, and this pulse can be used to enable capturing of data into a single latch element that is much smaller than a flip-flop. One way to improve the throughput of the design is to enable capturing of data on both edges of the system clock, known as dual-edge clocking. Dual edge clocking effectively doubles the throughput.

Various dual-edge flip-flop designs have been proposed, but they are generally more complex and larger than single-edge flip-flops. By contrast, a system using edge-detection and pulse generation can implement dual-edge clocking with no changes to the latch element itself by generating a pulse for both edges (rising and falling) of the system clock, thereby doubling the rate of pulses generated such that the latches capture data more frequently within the physical constraints of the circuit (e.g., for timing, power etc.). Dual-edge clocking also poses both opportunities and challenges for the validation of the design function, which for performance reasons is primarily performed using an abstraction of the design using simulation-efficient behaviors for state elements and clocking, and on the formal verification steps used to ensure that the abstract model is functionally equivalent to the low-level coding of the design that are used to implement the actual hardware circuitry.

### SUMMARY

One example embodiment provides an apparatus that may include a memory and at least one processor coupled to the memory, where the at least one processor may perform one or more of receive a logical model of a circuit written in a hardware description language (HDL), the logical model of the circuit comprising normalized and ratioed clocks, and simulation-efficient edge-triggered latches or flip-flops, translate the logical model of the circuit into a physical model of the circuit in the HDL via a software application, wherein at least one processor is configured to replace the normalized and ratioed clocks in the logical model of the circuit with a base system clock, divider logic generating hold waveforms to achieve ratioed behavior, and pulse-enabled latches, and replace the edge-triggered latches or flip-flops with pulse-generation logic and pulse-enabled latches, execute a formal verification which determines whether the logical model of the circuit is functionally equivalent to the physical model of the circuit, and display results of the formal verification via a graphical user interface (GUI) of the software application.

Another example embodiment provides a method that may include one or more of receiving a logical model of a circuit written in a hardware description language (HDL), the logical model of the circuit comprising normalized and ratioed clocks, and simulation-efficient edge-triggered latches or flip-flops, translating the logical model of the circuit into a physical model of the circuit in the HDL via a software application, wherein the translating comprises replacing the normalized and ratioed clocks in the logical model of the circuit with a base system clock, divider logic generating hold waveforms to achieve ratioed behavior, and pulse-enabled latches, and replacing the edge-triggered latches or flip-flops with pulse-generation logic and pulse-enabled latches, executing a formal verification which determines whether the logical model of the circuit is functionally equivalent to the physical model of the circuit, and displaying results of the formal verification via a graphical user interface (GUI) of the software application.

A further example embodiment provides a computer-readable hardware storage medium that includes instructions which when executed by a processor may cause the processor to perform one or more of receiving a logical model of a circuit written in a hardware description language (HDL), the logical model of the circuit comprising normalized and ratioed clocks, and simulation-efficient edge-triggered latches or flip-flops, translating the logical model of the circuit into a physical model of the circuit in the HDL via a software application, wherein the translating comprises replacing the normalized and ratioed clocks in the logical model of the circuit with a base system clock, divider logic generating hold waveforms to achieve ratioed behavior, and pulse-enabled latches, and replacing the edge-triggered latches or flip-flops with pulse-generation logic and pulse-enabled latches, executing a formal verification which determines whether the logical model of the circuit is functionally equivalent to the physical model of the circuit, and displaying results of the formal verification via a graphical user interface (GUI) of the software application.

### BRIEF DESCRIPTION OF THE DRAWINGS

FIG. 1 is a diagram illustrating a computing environment according to an embodiment of the instant solution.

FIG. 2 is a diagram illustrating a system for performing sequential equivalence checking according to the examples and features of the instant solution.

FIG. 3A is a diagram illustrating a process of performing sequential equivalence checking according to the examples and features of the instant solution.

FIG. 3B is a diagram illustrating a process of creating a composite model for sequential equivalence checking according to the examples and features of the instant solution.

FIG. 4 is a diagram illustrating a process of writing a coded design to a target device according to the examples and features of the instant solution.

FIG. 5A is a diagram illustrating a flow diagram, according to example embodiments.

FIG. 5B is a diagram illustrating a flow diagram, according to example embodiments.

### DETAILED DESCRIPTION

It is to be understood that although this disclosure includes a detailed description of cloud computing, implementation of the teachings recited herein is not limited to a cloud computing environment. Rather, embodiments of the instant solution are capable of being implemented in conjunction with any other type of computing environment now known or later developed.

According to an aspect of the example embodiments, there is provided a system which implements a modeling scheme to alleviate simulation performance issues of a coded design of a device such as a circuit, and an approach leveraging sequential equivalence checking to ensure correctness of the logical representation of the design against the circuit implementation bridging the waveform differences. The logical representation of the circuit (e.g., written in a very high-speed integrated circuit hardware design language (VHDL), etc.) may include dual edge clocked logic which is achieved by creating a special latch which detects both transitions of the clock, and latches data. Optimality of simulation performance is achieved by sharing the edge detectors in a clock-domain, and it has the same look and feel to the typical logic designer in terms of waveforms when studying the logic.

The modeling scheme of the system creates a gap between the waveforms in the physical and logical representation of the design. Furthermore, establishing functional correctness poses a challenge with equivalence checking. The example embodiments circumvent this by careful modeling of the clocks in the normalized logical representation of the design and the physical logical representation of the design given the differences (e.g., fifty percent duty cycle clocks versus pulsed clocks respectively, etc.) and stuttering of data appropriately in the equivalence checking set-up.

According to various embodiments, the system can assign explicit waveforms for each divided clock in the logical representation, and the grid clock and clock division (gating) signals in the physical design while ensuring proper alignment. In addition, the system can align counters used to generate divided clocks in the logical design with the counters used to generate clock-division gating signals in the physical design. The system can also stutter non-clock signals to avoid clock vs data race conditions that can result in capturing different data into the clocked dual edge flip flops (DFFs) versus the LCB-driven pulsed latches. The system allows the logical and physical representations to be modeled in a manner which is best suited for their respective contexts and leverages sequential equivalence checking to assure functional correctness of the physical implementation.

The system described herein provides a more efficient simulation process for a logical design of a circuit with respect to the physical design of the circuit. For example, the system may use latches as dual edge clocking logic that is sensitive to both the rising and falling edges of a fifty percent duty cycle clock. The system may verify the function of the logic efficiently in simulation and formal verification with the above representation. The system may establish equivalence of the logical and physical implementation of the coded design with sequential equivalence checking involving modeling of clocks and waveforms suitably across the two representations.

The system which executes the sequential equivalence checking described herein may be hosted within a software application, a service, or the like, which may be hosted by a host platform such as a cloud platform, a web server, a database, or the like.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or data center).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (Saas): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure, including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure, including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer can deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community with shared concerns (e.g., mission, security requirements, policy, and compliance considerations). It may be managed by organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service-oriented with a focus on statelessness, low coupling, modularity, and semantic interoperability. At the heart of cloud computing is an infrastructure that includes a network of interconnected nodes.

The instant features, structures, or characteristics as described throughout this specification may be combined or removed in any suitable manner in one or more embodiments. For example, the usage of the phrases “example embodiments,” “some embodiments,” or other similar language, throughout this specification refers to the fact that a particular feature, structure, or characteristic described in connection with the embodiment may be included in at least one embodiment. Thus, appearances of the phrases “example embodiments,” “in some embodiments,” “in other embodiments,” or other similar language, throughout this specification do not necessarily all refer to the same group of embodiments, and the described features, structures, or characteristics may be combined or removed in any suitable manner in one or more embodiments. Further, in the diagrams, any connection between elements can permit one-way and/or two-way communication even if the depicted connection is a one-way or two-way arrow. Also, any device depicted in the drawings can be a different device. For example, if a mobile device is shown sending information, a wired device could also be used to send the information.

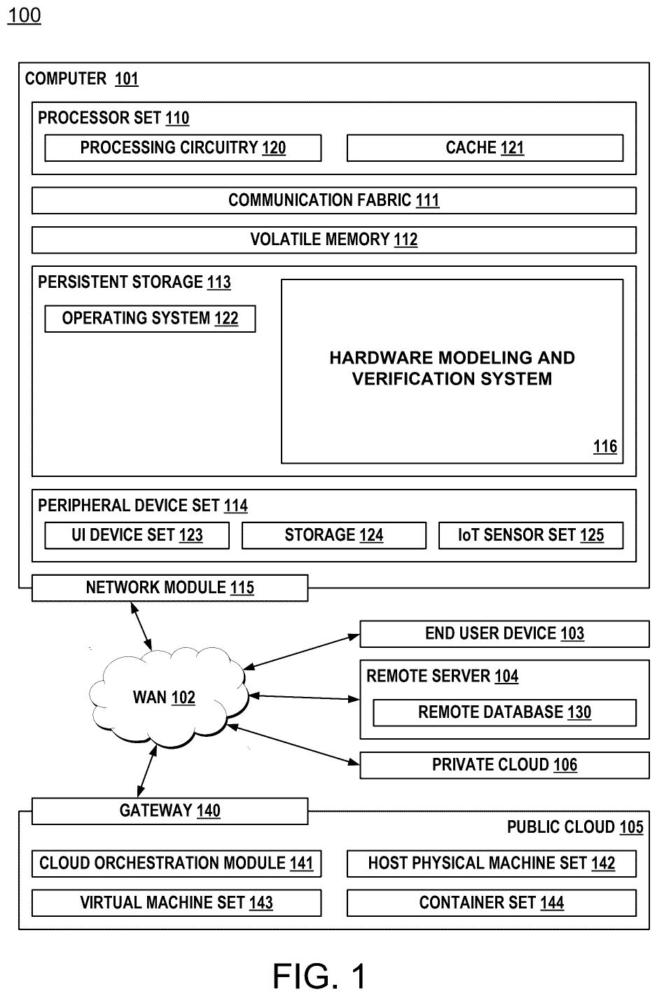

FIG. 1 illustrates a computing environment 100 according to an embodiment of the instant solution. Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again, depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Referring to FIG. 1, computing environment 100 contains an example of an environment for executing at least some of the computer code involved in performing the inventive methods, such as hardware modeling and verification system 116. In addition to block 116, computing environment 100 includes, for example, computer 101, wide area network (WAN) 102, end-user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 116, as identified above), peripheral device set 114 (including user interface (UI), device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smartphone, smartwatch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, the performance of a computer-implemented method may be distributed among multiple computers and/or between multiple locations. On the other hand, in this presentation of the computing environment 100, a detailed discussion is focused on a single computer, specifically the computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is a memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off-chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 116 in persistent storage 113.

COMMUNICATION FABRIC 111 is the signal conduction path that allows the various components of computer 101 to communicate with each other. Typically, this fabric comprises switches and electrically conductive paths, such as the switches and electrically conductive paths that make up buses, bridges, physical input/output ports, and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read-only memory (ROM), but typically at least a portion of the persistent storage allows writing of data, deletion of data, and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in block 116 typically includes at least some of the computer code involved in performing the inventive methods.

PERIPHERAL DEVICE SET 114 includes the set of peripheral devices of computer 101.

Data communication connections between the peripheral devices and the other components of computer 101 may be implemented in various ways, such as Bluetooth® connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smartwatches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer, and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi® signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data now known or to be developed in the future. In some embodiments, the WAN may be replaced and/or supplemented by local area networks (LANs) designed to communicate data between devices located in a local area, such as a Wi-Fi® network. The WAN and/or LANs typically include computer hardware such as copper transmission cables, optical transmission fibers, wireless transmission, routers, firewalls, switches, gateway computers, and edge servers.

END USER DEVICE (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer, and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, this data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanations of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as communicating with WAN 102, in other embodiments, a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both parts of a larger hybrid cloud.

Hardware designs traditionally use “flip-flop” registers for storage, which can be implemented as a pair of level-sensitive latches (L1->L2) which update based on an oscillating CLOCK input and an ENABLE. In a typical configuration, the L1 updates while CLOCK=0 and the L2 updates while CLOCK=1. The equivalent HDL code may be:

Source Code # 1

```
flip-flop:
  process (CLOCK, ENABLE, DATA)
  begin
    if (CLOCK = ‘0’) then
      if (ENABLE = ‘1’) then
        L1 <= DATA;
      end if;
    end if;
  end process;
  process (CLOCK, ENABLE, L1)
  begin
    if (CLOCK = ‘1’) then
      L2 <= L1;
    end if;
  end process;
  Q <= L2;
```

Another implementation which is better for simulation performance is edge detection circuitry feeding one latch, as using the flip-flop model above is not optimal due to the overhead of the two latches. This is especially true using event-based simulators. It is therefore common for both cases to use an edge-sensitive modeling for simulation employing a single storage element, like the following HDL code:

Source Code # 2

```
DFF:
  process (CLOCK)
  begin
    if (rising_edge (CLOCK)) then
      if (ENABLE = ‘1’) then
        FLOP <= DATA;
      end if;
    end if;
  end process;
  Q <= FLOP;
```

Logic synthesis tools can generally replace such a dual edge flip flop (DFF) with an equivalent flip-flop circuit (implemented using the two-latch flip-flop model above). An alternative approach uses a single level-sensitive latch instead of a flip-flop. In this scheme, the oscillating CLOCK input with a fifty percent duty cycle is replaced with a very narrow “pulse” generated at the desired edge of the input clock, such that the latch updates only during a narrow window. Below is an example of the code:

Source Code # 3

```
PULSED_LAT:
  process (PULSED_CLOCK,ENABLE,DATA)
  begin
    if (PULSED_CLOCK = ‘1’) then
      if (ENABLE = ‘1’) then
        LAT <= DATA;
      end if;
    end if;
  end process;
  Q <= LAT;
```

A further refinement may eliminate the ENABLE input, instead incorporating the enable condition into the incoming PULSED_CLOCK signal (i.e., external clock-gating). If the same ENABLE is used by multiple flip-flops, shared clock-gating can be performed which results in significant additional area savings. The external clock-gating and pulse-generation from the system clock (typically a clock mesh providing very predictable timing) is performed by local clock buffers (LCB). While the LCB logic is somewhat expensive, a single LCB can typically be shared by hundreds or even thousands of individual latches requiring the same clock domain and gating conditions, resulting in significant overall area savings. This very compact latch model is typically what is used in the physical HDL model, referred to here as P-HDL.

Source Code # 4

```
PULSED_ELAT:
  process (PULSED_ENABLE,DATA)
  begin
    if (PULSED_ENABLE = ‘1’) then
      LAT <= DATA;
    end if;
  end process;
  Q <= LAT;
```

Simulation to validate design function is executed on the logical model, here referred to as normalized HDL, or N-HDL. Simulation can potentially benefit from the simpler PULSED_LAT modeling, if the clock waveforms are carefully defined like “pulsed” clocks where the active duration is very short. This is especially true for cycle-based simulators, where a pulsed clock waveform would typically be asserted for only one “simulation cycle” and de-asserted for the remainder of the clock period, as opposed to a more typical fifty percent duty cycle. A design platform which can identify groups of either DFFs or PULSED_LATs that share common clocks and enable conditions and replace them with equivalent simplified PULSED_ELAT latches with accompanying LCBs (i.e., clock-gating and pulse-generator) logic, thereby enabling all of the benefits of fast simulation using efficient DFF, PULSED_LAT, or PULSED_ELAT models, as well as fast/small hardware circuits using physically efficient pulsed-latch design methodology.

Furthermore, clocks can be defined as a particular relative frequency (ratio) with respect to a base system clock, e.g. a 4-to-1 clock is a clock with period 4 times longer than the base system clock, which in the P-HDL are actually implemented as “HOLD signals” that are used by the LCBs to suppress specific generated pulses, e.g. suppressing 3 of every 4 pulses to effectively achieve a 4-to-1 clock ratio. If pulsed clocks are used in simulation, then slower N:1 pulsed clocks are easily generated from a reference 1:1 pulsed clock by suppressing N−1 of every N pulses. As described herein, normalized/ratioed clocks refer to clocks such as a “clock # to 1”, where # is a positive integer value.

Logical designs (in N-HDL) that embed hard IP components (such as memory array, typically written in P-HDL) that already contain internal LCB logic pose challenges for integration into a simplified simulation model that use abstract (i.e., normalized) and divided (i.e., ratioed) Nto1 clocks. The interfaces of such IP components have, as inputs, the system clock and the HOLD gating signals used by the internal LCBs to suppress unwanted pulses. The abstract divided clock (in N-HDL) cannot be directly connected to the hard IP. Therefore, a special simulation component, CLK2HOLD, is used to generate the desired HOLD gating from the abstract divided clock. If N:1 pulsed clocks are used in simulation, then the implementation of the CLK2HOLD is relatively straightforward: the HOLD signal just needs to be de-asserted for some duration whenever the ratioed clock pulse is asserted. For example:

HOLD <= not( CLK_IN or delay(CLK_IN, 1) );
Source Code # 5

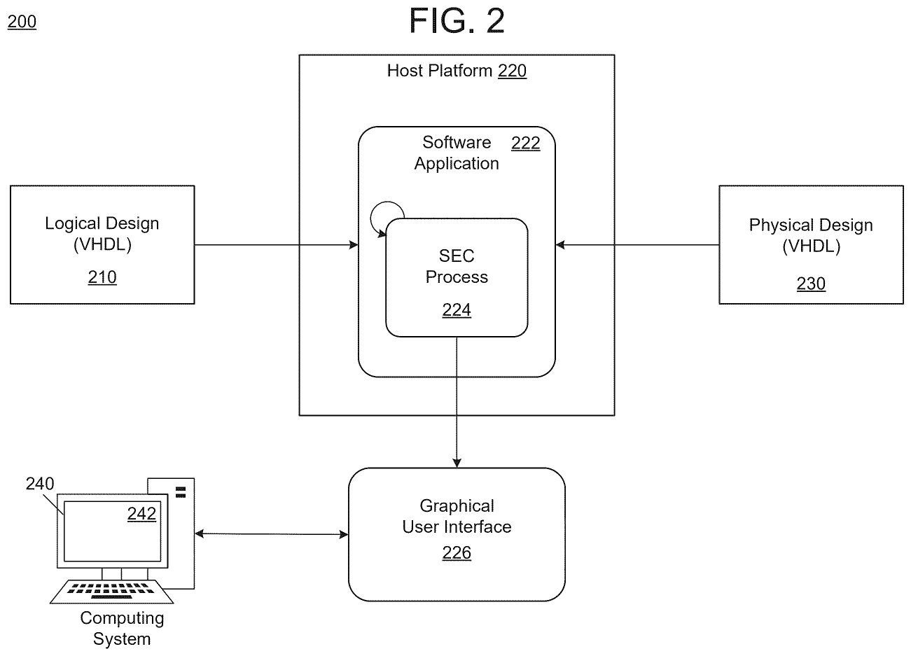

FIG. 2 illustrates a system 200 for performing sequential equivalence checking according to the examples and features of the instant solution. In the examples herein, the sequential equivalence checking (SEC) may be performed through a formal verification process. Referring to FIG. 2, the system 200 includes a host platform 220 that hosts a software application 222 capable of performing the formal verification described herein. For example, the software application 222 may execute a sequential equivalence checking (SEC) process 224. In this example, the software application 222 may receive a logical design 210 of a target device such as an integrated circuit and a physical design 230 of the target device, both of which are written in HDL. For example, the logical design 210 and the physical design 230 may be written using two forms of hardware description languages used to describe logical circuitry.

For example, the logical design 210 may be written in N-HDL while the physical design 230 may be written in P-HDL. P-HDL requires much more complex building blocks to achieve the dual edge behavior through a LCB, whereas this behavior can be achieved in N-HDL by creating a latch that will read data on both the positive and negative edge of the system clock. Since the components work very differently, the software application 222 may be used to ensure that the ultimate behavior of N-HDL is the same as P-HDL.

In some embodiments, the software application 222 may convert the logical design 210 in N-HDL into the physical design 230 in P-HDL, which then ultimately gets converted into a circuit. Sequential equivalence checking is used by the software application 222 during the SEC process 224 to compare output behavior in the N-HDL (the logical design 210) against output behavior in the P-HDL (the physical design 230) at all points in time when each design is given the same randomized (i.e., non-deterministic) input stimuli. As such, the software application 222 can ensure that the behavior of the logical design 210 (in N-HDL) is the same as the physical design 230 (in P-HDL), despite differences in the actual components in use.

The results of the SEC process 224 may include indications that the two designs are functionally equivalent. As another example, the results may include indications that the two designs are not functionally equivalent, and information about what parts of the designs are not equivalent. The results may be output to a graphical user interface (GUI) 226 which may be viewed by a computing system 240 with a display device 242. For example, the computing system 240 may connect to the host platform 220 over a computer network. In this case, the software application 222 may be a progressive web application or back-end of an application that is accessed via a URL, or the like, of the software application 222.

In the example embodiments, P-HDL refers to HDL that more accurately describes full behavior of the actual hardware, including so-called “pervasive” logic used only for manufacturing testing or debug analysis of failing hardware. N-HDL refers to normalized HDL that abstracts away much of these physical design specific components, and gives us a simplified, purely functional view of the circuit. It is also possible that the N-HDL represents even the base functionality differently than implemented in the P-HDL while providing the same end function, such as the details in clocking and latching of data. Both of these optimizations significantly speed up simulation of N-HDL vs P-HDL.

As further described herein, simulation performed by the software application 222 may ensure that the functional operation of HDL is correct. For example, if there is an operation that adds two integers, the simulation can ensure that the circuit produces the correct sum. As further described herein, “modeling the clock signal” refers to modeling the clocking behavior of the P-HDL, which is often more complex, in N-HDL. The software may be used to model P-HDL clocks in N-HDL using simpler logic while trying to achieve the same overall behavior. The process does not just refer to modeling a clock signal specifically, but rather how “clocking” as a concept works. The importance here is placed on how clocks interact with latches in the design, and how that affects overall functionality of the design.

In the case of N-HDL, clocks can be divided into fifty-fifty duty cycle waveforms (e.g., clock n to 1), but the latches will capture data on both the edges of this divided clock. The physical design 230 in the P-HDL, may include clocks and latches that interact via local clock buffers (LCBs). In both cases, the system 1-to-1 clock may be used as a base reference point. And in both cases, this system clock may be created as an oscillating signal defined by what a designer defines in the simulation tools.

As noted herein, the software application 222 may implement a formal verification process that performs the SEC process 224. Formal verification may be used to guarantee that the physical P-HDL modeling remains functionally equivalent to the logical N-HDL modeling. Specifically, a very scalable form of formal verification known as “sequential equivalence checking” from correlated initial states, referred to as just SEC, can be used, applied in a hierarchical and compositional fashion on key modules within the design hierarchy.

However, some challenges exist. With few exceptions as noted below, it is generally possible to let SEC initialize the designs to an entirely random, though correlated, initial state. Thus, functional equivalence is proven for all possible initializations, even those that are not actually practically reachable. If the module under test contains clock dividers, then it is necessary that the output waveforms are “aligned” between the logical clock dividers (N-HDL) and physical HOLD signal generation (P-HDL) models. In cases where it is not straightforward to correlate random initial values of the internal counters used to implement the dividers, the counters can be initialized to concrete states known to be aligned.

If the module under test does not contain the dividers that generate the ratioed clocks (N-HDL) or ratioed HOLD gating (P-HDL), such that the ratioed clock or HOLD are inputs to the module, then it is preferred to specify consistent “ideal” waveforms for both the clocks and the associated HOLD signals. In other words, the tools can generate input values that would emulate what an expected ratioed clock or hold signal would look like if it were created via a clock divider or LCB. Any clocks and HOLD signals that are verification observation points (e.g., primary outputs or inputs of “black-boxed” modules) can be validated against these same ideal waveforms to ensure compositional correctness. One embodiment applies the ideal waveforms based on port name conventions (e.g., if an input pin named “clock_4to1” is identified, the system could generate a ratioed 4-to-1 N-HDL clock), but other mechanisms involving attributes or other bookkeeping are possible.

The physical (P-HDL) model contains additional behavior that is not part of the main-line function present in the logical (N-HDL) model, such logic related to manufacturing test and hardware debug analysis, including scan-chains and additional controls specific to precise hardware timing concerns present in the LCB logic. The SEC is concerned only with the main-line function that is present in both models, so it is necessary to constrain various “pervasive” input signals in the physical (P-HDL) model as needed to disable the additional function. Any pervasive signals that are verification observation points (e.g., primary outputs or inputs of “black-boxed” modules) can be validated against these same constraint values to ensure compositional correctness.

There is a race condition where DFF modeling and pulsed-latch modeling may capture conflicting data values, since the pulse generated by an LCB will occur slightly later than the edge of the input clock. This concern is aggravated in cycle-simulation and SEC environments where the “pulse” is modeled as a full simulation cycle. For SEC, the race condition is avoided by “stuttering” data and clock signals at primary input/output boundaries in an out-of-phase fashion. Put simply, data signals are randomly driven, but only allowed to transition on even-numbered simulation cycles, and clocks are either randomly driven but only allowed to transition on odd-numbered simulation cycles or they are driven to ideal waveforms that only transition on odd-numbered simulation cycles.

It is becoming impractical to increase the performance of a hardware device by simply increasing the system clock speed due to physical limitations, especially power consumption and noise generation. An alternative way to increase (e.g., double, etc.) the throughput of the circuit is to do more during each system clock cycle. In a methodology using pulse-based latches, this can be achieved by generating a pulse on both edges of the system clock, referred to as dual-edge clocking, which effectively doubles the throughput, without changing the design of the latch element itself.

In the example embodiments, a mix of single edge DFFs and dual edge DFFs can be used to facilitate interfacing between fast and slow clock domains and/or to allow using dual-edge on a slower grid clock to reduce overall power consumption. The simple clocks are still specified with a particular relative frequency with respect to a base clock, and the software application automatically transforms it into an efficient pulsed latch design using a clock grid with local clock buffers (LCBs), but the dual edge capable LCBs can generate pulses on both edges of the grid clock, and hence can clock the pulsed latches twice as fast as before. A new challenge is that IP elements may expect to be used in a dual edge context, and therefore already contain internal dual edge LCBs.

The logical representation and simulation modeling for such a dual-edge scheme poses challenges, however. Pulsed clock waveforms cannot be easily “doubled” in frequency since there is no reference for the mid-point of the clock cycle. The need is to ensure logical representation of the design used for simulation is functionally equivalent to the hardware circuit implementation. Embedded IP blocks containing dual-edge LCBs have more complex interfacing requirements (additional even/odd HLD gating). It is also desirable to enable easy migration of a large base of existing HDL designs when moving from single-edge to dual-edge design point.

The example embodiments address these challenges by providing a software application that implements a design modeling scheme to achieve efficient simulation performance for dual-edge designs and automatic translation to dual-edge pulsed-latch hardware implementation, and leveraging sequential equivalence checking to ensure correctness of the logical representation of the design against the circuit implementation.

In some embodiments, ideal clock waveforms are defined with fifty percent duty cycles instead of pulsed clock waveforms. In some embodiments, the logical representation of dual edge clocked logic in N-HDL is achieved by creating a new flip-flop behavior which detects and updates on both transitions of the clock. This is easily modeled in simulation by detecting an event on the clock which is even simpler than detecting a specific edge as done in the single-edge DFF. The DE_DFF has the same interface as a typical DFF, such that it is a simple substitution when migrating a design from single-edge to a dual-edge design point. The non-pulsed clock waveforms (i.e., fifty percent duty cycle) ensure that data transitions in a way familiar to designers used to single-edge clocking. Below is an example of the code of the modeled DE_DFF.

Source Code # 6

```
DE_DFF:
  process (CLOCK)
  begin
    if (CLOCK’event) then
      if (ENABLE = ′1′) then
        FLOP <= DATA;
      end if;
    end if;
  end process;
  Q <= FLOP;
```

The software application can identify groups of DE_DFFs that share common clocks and enable conditions and replace them with equivalent simplified PULSED_ELAT latches with accompanying DE_LCBs (i.e., clock-gating and dual-edge pulse-generator) logic, thereby enabling all of the benefits of fast simulation using efficient DE_DFF models as well as fast/small hardware circuits using physically efficient dual-edge pulsed-latch design methodology.

Ratioed N:1 clock waveforms are also generated to have a fifty percent duty cycle, allowing these clocks to be used with dual-edge flip-flops as well. This introduces a greater discrepancy between the logical clock waveform used in simulation and the dual-edge pulsed clock with “hold” gating used in the hardware circuit. Dividing a fifty percent duty cycle clock waveform is also more challenging than dividing a pulsed clock waveform since the midpoint needs to be calculated. Below is an example of the code.

Source Code # 7

```
CLK_DIVIDE:
process (CLOCK)
begin
  if (CLOCK’event) then
    if (counter = (2 * RATIO))
      counter <= 0;
    else
      counter <= counter + 1;
    end if;
  end if;
end process;
process (RATIO, counter)
begin
  if ((counter = 0) or (counter = RATIO)) then
    divided_clock <= not(divided_clock)
  end if;
end process;
```

In the above example, CLOCK is the system clock, and RATIO is an integer input that determines the division ratio. For example, if RATIO is 4, then a 4-to-1 clock output with fifty percent duty cycle is generated. The 4-to-1 clock is high for two periods of CLOCK and low for two periods of CLOCK, sometimes referred to as “2 up/2 down”. Intuitively, this logic finds the “midway” point of a divided clock where the clock should toggle from either 0 to 1 or 1 to 0.

Alternatively, it is often preferred that multiple clock dividers remain globally synchronized after a change to the RATIO value, which can be accomplished by using a free-running counter that resets independently from the RATIO input. In the following example, the divider toggles the output divided clock whenever the counter is evenly divisible by RATIO/2. The RATIO is restricted here to being a power-of-2 value.

Source Code # 8

```
CLK_DIVIDE_sync
process (CLOCK)
begin
  if (falling_edge(CLOCK)) then
    counter <= counter + 1;
  end if;
end process;
process (RATIO, counter)
begin
  if ((counter and (RATIO/2) = 0) then
    divided_clock <= not(divided_clock)
  end if;
end process;
```

The counter in the above example has a fixed width of N bits, and so wraps back to 0 once incremented to 2\hat{ }N. The RATIO also has a fixed width of N bits. The line “if ((counter and RATIO/2)=0)” uses a “bit-wise logical and” to efficiently implement a modulo operation, since the RATIO is known to be a power-of-2.

In some embodiments, ratioed N:1 clocks feeding DE_DFFs may be reimplemented using DE_LCBs feeding traditional pulsed latches using typical N:1 HOLD gating in P-HDL. As another example, ratioed N:1 clocks feeding dual edge DFFs may alternatively be reimplemented using single edge LCBs feeding traditional pulsed latches but using faster (N/2):to 1 HOLD gating in P-HDL. Single edge LCBs are significantly smaller than DE_LCBs.

In some embodiments, the CLK2HOLD function from before is no longer trivial to implement due to fifty percent duty cycles. A new version based on counting edges of the base clock occurring between edges of the input divided clock has been developed as shown in the code below:

Source Code # 9

```
CLK2HOLD:
process (divided_clock, clock)
begin
  if (divided_clock = 0) then
    counter <= counter + 1;
  elsif(divided_clock = 1) then
    counter <= counter − 1;
  endif;
end process;
process (counter)
begin
  if (counter <= 1) then
    hold <= 0;
  else:
    hold <= 1;
  endif;
end process;
```

In short, this code will count base clock edges upwards while the divided clock is 1, and will count back downwards when the divided clock is 0. In the case of a fifty percent duty cycle clock, this means that the number of times the counter increments will be equal to the number of times the counter decrements. When the counter counts down to near 0, the HOLD signal is de-asserted prior to the falling clock edge, thus allowing a clock pulse to be generated for that falling edge (recall HOLD signals suppress the LCBs from generating clock pulses, so de-asserting to 0 means no longer suppressing the pulses).

As an example, with a 4-to-1 fifty percent duty cycle clock, the signal of the divided_clock=0 0 0 0 1 1 1 1 (repeated). While the divided clock is 0, the counter will count up to 4, and then when the clock is 1 the counter will count back down to 0, but once the count is 1 or 0, the HOLD is de-asserted to allow a clock pulse to be repeated. In other words, a clock pulse is generated on the falling edge of the divided_clock. By de-asserting HOLD prior to the actual falling edge, race conditions in the LCB are avoided in the example embodiments.

In the example embodiments, a ‘CLK2HOLD_de’ function is used to interface with IP elements or hierarchical sub-unit with internal dual-edge clocking using DE_LCBs. Note that for ease of specification, it is convenient for the input divided clock to use the same ratio as used for logic surrounding the IP. This typically means that the divided clock (N-HDL) is a factor of 2 slower than the desired HOLD signals (P-HDL). Therefore, the CLK2HOLD_de component may effectively double the frequency of the input divided clock. An implementation using two of the edge counters from CLK2HOLD, one for each polarity of the input divided clock, has been developed. This implementation is for even ratioed clocks and 1-to-1 clocks only.

Source Code # 10

```
CLK2HOLD_de:
process (divided_clock, clock)
begin
  if (divided_clock = 0) then
    counter_falling <= counter_falling + 1;
    counter_rising <= counter_rising − 1;
  elsif(divided_clock = 1) then
    counter_falling <= counter_falling − 1;
    counter_rising <= counter_rising + 1;
  endif;
end process;
process (counter_falling, counter_rising)
begin
  if (counter_rising <= 1) then
    hold_rising <= 0;
  else
    hold_rising <= 1;
  endif;
  if (counter_falling <= 1) then
    hold_falling <= 0;
  else
    hold_falling <= 1;
  endif;
hold_odd <= hold_falling and hold_rising;
hold_even <= ‘0’ when (divided_clock == 1to1) else ‘1’.
end process;
```

Essentially, the hold_odd signal is similar in concept to the regular hold signal, but in this case the system can generate a clock pulse on the rising edge of the divided clock as well as the falling edge. This replicates the regular CLK2HOLD logic and then just reverses conditions of how to count up and down. Using a 4-to-1 ratio will cause an output of 0 0 0 0 1 1 1 1, however in this case, assuming the counter is already at 4 from a previous cycle, the system may first count down from 4 to 0, triggering a pulse at the mid cycle rising edge. Then the count goes back up to 4 to prepare for the next rising edge.

Combining these two signals using a “logical and” produces a hold signal that will de-assert the HOLD seen by an LCB before rising and falling edges. The function for hold_even is simpler. Since the only allowed ratio that would require a pulse to be generated from the rising edge of the system clock is the 1-to-1 case, the hold_even should be de-asserted when the input divided_clock is determined to be a 1-to-1 clock, and asserted otherwise. It should be noted that dual-edge clocking is not limited to even valued ratios. More complex hold_even and hold_odd waveforms that support 3-to-1 and other odd-valued ratios are possible, achieved by suppressing alternating rising and falling edges of the system clock.

Logic components are often designed to be used in multiple contexts, including with multiple different clock ratios. In such cases, the interface of the component does not define a specific ratio for the normalized and ratioed clock (in N-HDL) and the HOLD gating (in P-HDL). This poses a challenge for equivalence checking. In such cases, the component must be checked for all possible legal configurations. In the example embodiments, this checking is accomplished in a single run of equivalence checking by defining the abstract clock inputs as list of valid waveforms that are selected non-deterministically, generating corresponding HOLD signals, using a transform similar to CLK2HOLD or CLK2HOLD_de, correlating any abstract clock outputs to the corresponding HOLD signal outputs (e.g. at primary outputs of the current design under test or at inputs of any components that are “black-boxed” (i.e. not present) in the design under test, and validating that the HOLD signals are de-asserted (0) when the corresponding abstract clock edge is detected and asserted on all other edges of the system clock.

In the example embodiments, formal verification, and specifically “SEC from correlated initial states” can be used to guarantee that the physical P-HDL modeling remains functionally equivalent to the logical N-HDL modeling. There are new challenges and solutions specific to dual-edge clocking. However, if the module under test contains clock dividers, then it is necessary that the output waveforms are “aligned” between the logical clock dividers (N-HDL) and physical HOLD signal generation (P-HDL) models. With fifty percent duty cycle modeling, the clock divider is more complex and more difficult to align with the HOLD signal generation.

With dual-edge clocking, the DE_LCB components may utilize two independent HOLD signals, usually denoted as HOLD_EVEN and HOLD_ODD, corresponding to the rising and falling edges of the system clock, respectively. When encountered on a hierarchical boundary, whether a primary input/output of the current module or an input/output of a “black-boxed” sub-module or for hard IP, a clear understanding of the effective ratio of the port is necessary to assume or check against a predefined ideal waveform. One embodiment applies the ideal waveforms based on port name conventions, but other mechanisms involving attributes or other bookkeeping are possible. As is the case with single-edge clocking, a race condition exists where DFF modeling and pulsed-latch modeling may capture inconsistent data values, and with dual-edge clocking this can happen on either edge of the system clock. This implies that the minimum viable clock period for the system clock is increased from 2 simulation cycles (1 up, 1 down) to 4 simulation cycles (2 up, 2 down), which can increase complexity of SEC. As an optimization, however, if it is detected that a given module does not utilize DE_DFFs or DE_LCBs, the SEC can revert to using a system clock with period 2 simulation cycles without loss of compositional correctness.

The example embodiments provide numerous benefits/practical applications. For example, the solution provides efficient logical representation of a dual-edge flip-flop (DE_DFF) for modeling and verification using fifty percent duty cycle clocks and clock division. In addition, divided clocks feeding dual edge DFFs may be reimplemented using dual edge LCBs feeding traditional pulsed latches. Divided clocks feeding dual edge DFFs may alternatively be reimplemented using single edge LCBs feeding traditional pulsed latches but using faster (i.e., less divided) HLDs. Additionally, new translators (CLK_DIVIDE and CLK_DIVIDE_sync), which operate by counting input clock edges, are used to generate new waveforms with periods that are arbitrary integer multiples of the original period. Also, provided is a method to generate dual edge pulsed physical clocks derived from logical clocks only. This is required to interface with components either already synthesized or manually written to utilize physical dual edge LCBs feeding traditional pulsed latches are optimized for area, power, and performance in physical design. The example embodiments also provide new translator (CLK2HOLD_de) function based on up/down counting of base system clock pulses between edges of the input divided fifty percent duty cycle clock is used to interface with IP elements with internal DE_LCBs requiring a pair of HOLD signals. The system can create an effective approach for sequential equivalency checking between the logical dual edge circuit and its synthesis-mapped counterpart, perform equivalence check of divided clocks with configurable ratios versus generated HOLD gating signals by utilizing non-deterministic selection from a list of valid N:1 ratios, and perform a sampling-based equivalence check where divided fifty percent duty cycle clock and divided HOLD signals are checked for consistency in specific time steps only, as determined by the base system clock frequency.

The system herein allows the logical and physical representations to be modeled in a manner which is best suited for it, and leverages sequential equivalence checking to assure functional correctness of the physical implementation.

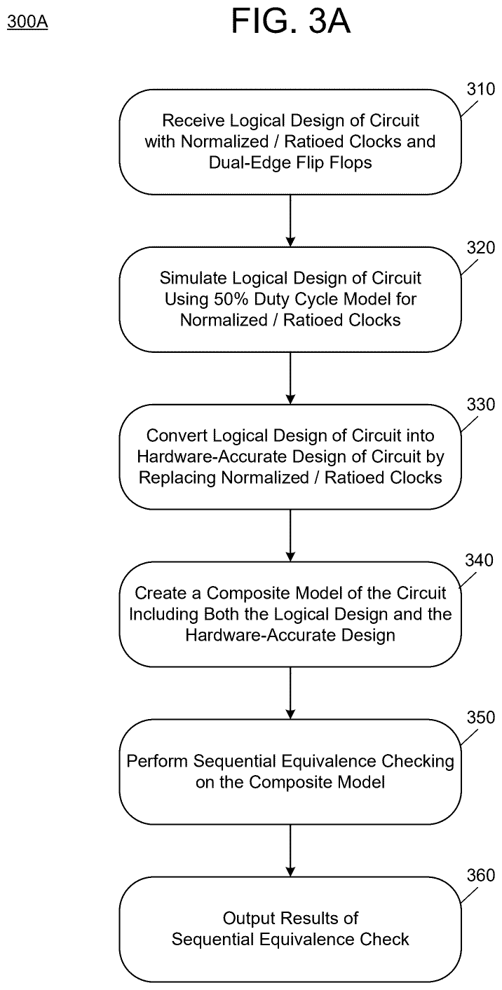

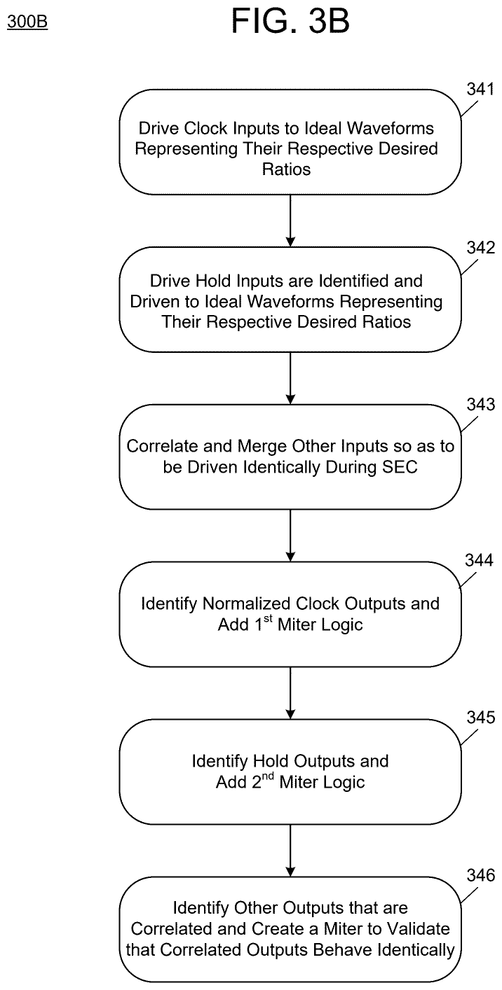

FIG. 3A illustrates a process 300A of performing sequential equivalence checking according to the examples and features of the instant solution, and FIG. 3B illustrates a process 300B of creating a composite model for sequential equivalence checking according to the examples and features of the instant solution.

In the examples here, sequential equivalence checking validates the functional equivalence of two design models, typically using formal (and informal) methods to prove or disprove that the two designs produce identical results for identical (correlated) input stimuli. Unlike combinational equivalence checking (CEC), SEC does not require a strict correlation of internal state elements and will flag a mismatch only if a test model (input value sequence), when applied to the corresponding inputs of both designs with respect to their specified initial states, differentiates their outputs.

The SEC process can be augmented with optional additional configuration data. For example, constraints or driving environments that restrict the input sequences to preclude illegal input stimuli which may have been used as don't cares in in design optimization may be added. As another example, initialization data for internal state elements, which could include concrete values, correlated (or non-correlated) non-deterministic values, or logic representing symbolic relationships to other state elements. The SEC process can also be augmented with correlation information of inputs and outputs, modified checking logic for outputs that are known and expected to not be functionally identical between the two design models, directives to excise sub-modules of the two designs, sometimes referred to as “black-boxing”, resulting in additional inputs and outputs for the SEC, which must be correlated and validated just like the primary inputs and outputs. Black-boxing is often beneficial to SEC scalability when removing large sub-components, memory arrays, sequentially-deep components (such as linear feedback shift register logic), and complex arithmetic components like multipliers or dividers. Black-boxing is also used in a hierarchical SEC flow to achieve more scalability on very large hierarchical designs than possible using monolithic SEC. As another example, the SEC can be augmented with directives to declare expected internal equivalent nets, which will be added as additional comparison points, but also used to simplify the SEC complexity.

To perform an SEC of a logical model and a physical model of the same design, a “composite model” may be generated containing both design models, with correlated inputs “merged” and driven identically, and with additional checking logic (referred to as a “miter”) added to detect non-equivalent values at correlated outputs. In most cases, this additional logic is a simple XOR gate, which produces a logical-1 when its inputs have different values, and a logical-0 otherwise. Formal analysis methods are used to discover input sequences that can result in a logical-1 at any miter output, or prove that no such input sequence exists to produce a logical-1 at any miter output.

FIG. 3A illustrates a process of performing the SEC according to the examples herein. Referring to FIG. 3A, a logical design (e.g., N-HDL) may be received by the system, in 310. As another example, the logical design may be written using a predefined programming language such as VHDL. Here, the logical design may include normalized/ratioed clocks (e.g., “clock_# to 1”, where # is an integer divisible by 2). The logical design may also include a mix of single-edge (DFF) and dual-edge (DE_DFF) triggered flip flops, DFF and DE_DFF, respectively.

In 320, the system may simulate the logical design using a fifty percent duty cycle modeling for all “clock_# to 1” clocks. This simulation is highly efficient and scalable due to using the efficient flipflop and clock division modeling. In 330, the system may synthesize the logical design into a hardware-accurate physical design in HDL (P-HDL) by replacing normalized/ratioed clocks and flipflops with (i) a base system clock (non-ratioed), (ii) divider logic, generating HOLD waveforms to gate the system clock to achieve effective ratioed behavior, (iii) a mix of single-edge and dual-edge local clock buffers (LCBs) that generate gated, ratioed pulses, and (iv) physically efficient pulse-enabled latches (PULSED_ELAT).

In 340, the system may create a “composite” model consisting of both the logical design in N-HDL and the physical design in P-HDL. In 350, the system can apply formal property checking analysis to the “composite” model to discover any non-equivalence or to prove that the designs are indeed functionally correct. Here, the system may perform a sequential equivalence check of the composite model. A further example of the process performed in 340 is shown and described with respect to FIG. 3B. In 360, the results of the sequential equivalence check may be displayed on a graphical user interface (GUI) of the software application.

A more detailed process performed in 340 is shown and described with respect to FIG. 3B. Referring now to FIG. 3B, in 341, clock inputs (both normalized/ratioed and system clocks) are identified and driven to ideal waveforms representing their respective desired ratios. The identification could be done by signal naming convention, by HDL attribute, or any other means. In 342, HOLD inputs are identified and driven to ideal waveforms representing their respective desired ratios. The identification could be done by signal naming convention, by HDL attribute, or any other means. In 343, other inputs are correlated and merged, so as to be driven identically. The correlation may be performed by signal name, by HDL attribute, or any other means. In 344, normalized clock outputs are identified, and miter logic #1 is added to produce a logical-1 if the clock output differs from the ideal waveform at any time. The identification of the clock outputs could be done by signal naming convention, by HDL attribute, or any other means. In 345, HOLD outputs are identified, and miter logic #2 is added to produce a logical-1 if HOLD output differs from the ideal waveform in any cycle where the system clock is transitioning, which is the only time the value of the HOLD signal is relevant. In 346, other outputs are correlated, and a miter is created to validate that correlated outputs have identical behavior. The correlation may be performed by signal name, by HDL attribute, or any other means.

Extensions to the process are also possible. For example, when writing N-HDL that interfaces with hard-IP that may employ internal dual-edge (DE_LCB) clocking and therefore has HOLD signals as inputs, not normalized/ratioed clocks, the normalized/ratioed clocks can be converted into equivalent HOLD signals to connect to that IP. This is performed with the CLK2HOLD and CLK2HOLD_de components described herein. In some embodiments, during the synthesis from the logical design in N-HDL to the physical design in P-HDL, when a normalized/ratioed clock is used by a DE_DFF and clock ratio is a multiple of 2, then an optimization is possible. Instead of synthesizing clock_N-to-1->DE_DFF into hold_Nto1->DE_LCB->PULSED_ELAT, this can be synthesized into hold_Mto1->LCB->PULSED_ELAT, where M=N/2, saving the additional area cost of the DE_LCB over the LCB.

Additional extensions are also possible. For example, when writing N-HDL in cases where the normalized clock has a configurable ratio, the ratio is not implicit in the signal name itself. Instead, the CLK_DIVIDE or CLK_DIVIDE_sync components can be used to generate a higher-ratioed normalized clock from a non-ratioed or lower-ratioed clock.

As another example, in cases where the normalized clock has a configurable ratio, instead of driving clock inputs with a single ideal waveform, the system may introduce driving logic that randomly selects 1 of several legal, ideal normalized/ratioed clock waveforms. Further, instead of adding a miter on clock and hold outputs to compare to a single ideal waveform, the system may identify the normalized/ratioed clock in the N-HDL, add logic to generate a pulse on the desired edge(s) of the clock, identify the HOLD signal(s) in the P-HDL that correlate to this normalized/ratioed clock, and add miter logic #2 to produce a logical-1 if the HOLD output differs from the modified normalized clock in any cycle where the system clock is transitioning, which is the only time the value of the HOLD signal is relevant.

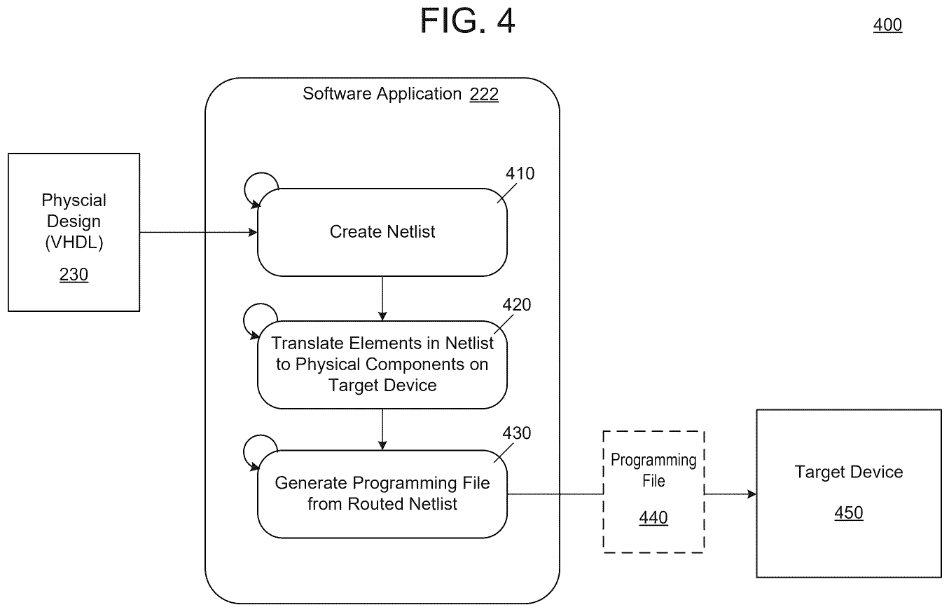

FIG. 4 illustrates a process 400 of writing a coded design to a target device according to the examples and features of the instant solution. Referring to FIG. 4, after validating the functionality of the logical design 210 and the physical design 230 are the same, the software application 222 may write the physical design 230 to a target device 450, such as an integrated circuit. Here, the software application 222 may create a netlist in 410 by simulating the physical design 230. In 420, the software application may translate elements in the netlist to physical components/wires on the target device 450. In 430, the software application 222 may generate a programming file 440 that includes the logic of the physical design 230, and embed the programming file 440 on the target device thereby embedding the logic in the target device 450.

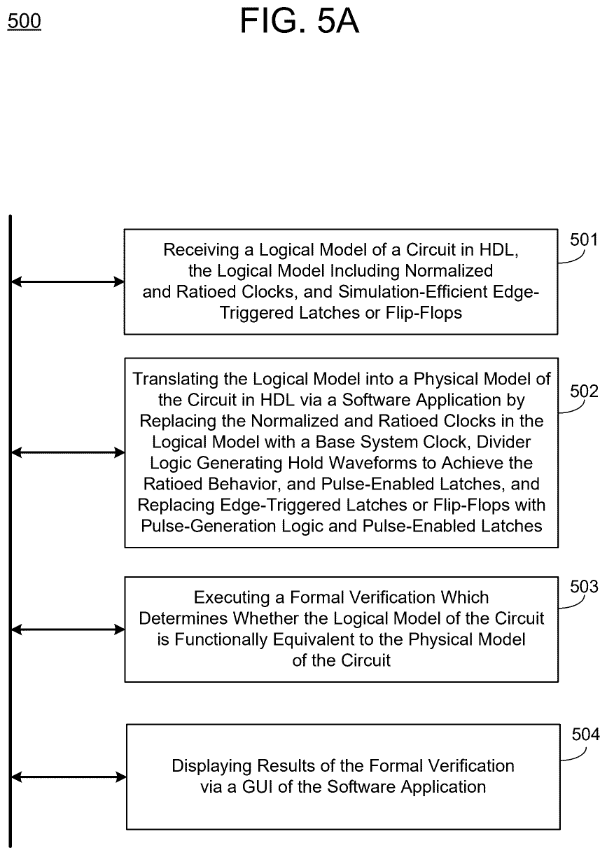

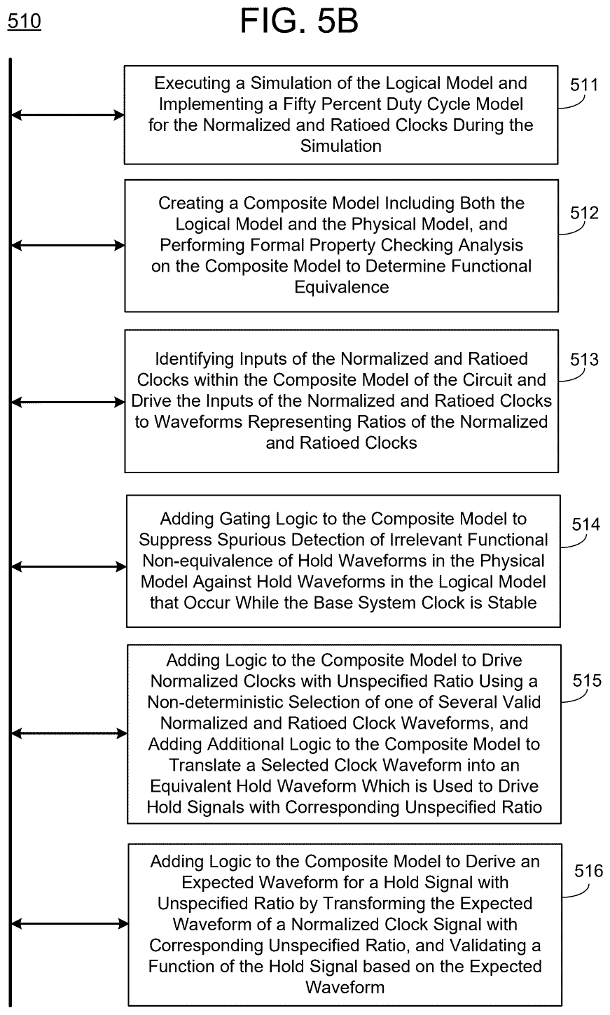

FIG. 5A illustrates a flow diagram of a method 500, according to example embodiments. Referring to FIG. 5A, in 501, the method may include receiving a logical model of a circuit written in a hardware description language (HDL), the logical model of the circuit comprising normalized and ratioed clocks, and simulation-efficient edge-triggered latches or flip-flops. In 502, the method may include translating the logical model of the circuit into a physical model of the circuit in the HDL via a software application, wherein the translating comprises replacing the normalized and ratioed clocks in the logical model of the circuit with a base system clock, divider logic generating hold waveforms to achieve ratioed behavior, and pulse-enabled latches, and replacing edge-triggered latches or flip-flops with pulse-generation logic and pulse-enabled latches. In 503, the method may include executing a formal verification which determines whether the logical model of the circuit is functionally equivalent to the physical model of the circuit. In 504, the method may include displaying results of the formal verification via a graphical user interface (GUI) of the software application.

FIG. 5B illustrates a flow diagram of a method 510, according to example embodiments. Referring to FIG. 5B, in 511, the method may include executing a simulation of the logical model and implementing a fifty percent duty cycle model for the normalized and ratioed clocks during the simulation. In 512, the method may include creating a composite model including both the logical model and the physical model, and performing formal property checking analysis on the composite model to determine functional equivalence. In 513, the method may include identifying inputs of the normalized and ratioed clocks within the composite model of the circuit and drive the inputs of the normalized and ratioed clocks to waveforms representing ratios of the normalized and ratioed clocks.

In 514, the method may include adding gating logic to the composite model to suppress spurious detection of irrelevant functional non-equivalence of hold waveforms in the physical model against hold waveforms in the logical model that occur while the base system clock is stable. In 515, the method may include adding logic to the composite model to drive normalized clocks with unspecified ratio using a non-deterministic selection of one of several valid normalized and ratioed clock waveforms, and adding additional logic to the composite model to translate a selected clock waveform into an equivalent hold waveform which is used to drive hold signals with corresponding unspecified ratio. In 516, the method may include adding logic to the composite model to derive an expected waveform for a hold signal with unspecified ratio by transforming the expected waveform of a normalized clock signal with corresponding unspecified ratio, and validating a function of the hold signal based on the expected waveform.

The above embodiments may be implemented in hardware, in a computer program executed by a processor, in firmware, or in a combination of the above. A computer program may be embodied on a computer readable medium, such as a storage medium. For example, a computer program may reside in random access memory (“RAM”), flash memory, read-only memory (“ROM”), erasable programmable read-only memory (“EPROM”), electrically erasable programmable read-only memory (“EEPROM”), registers, hard disk, a removable disk, a compact disk read-only memory (“CD-ROM”), or any other form of storage medium known in the art.

An exemplary storage medium may be coupled to the processor such that the processor may read information from, and write information to, the storage medium. In the alternative, the storage medium may be integral to the processor. The processor and the storage medium may reside in an application-specific integrated circuit (“ASIC”). In the alternative, the processor and the storage medium may reside as discrete components.

What is claimed is:

1. An apparatus comprising:
a memory; and
at least one processor coupled to the memory, at least one processor configured to:
receive a logical model of a circuit written in a hardware description language (HDL), the logical model of the circuit comprising normalized and ratioed clocks, and simulation-efficient edge-triggered latches or flip-flops
translate the logical model of the circuit into a physical model of the circuit in the HDL via a software application, wherein the at least one processor is configured to replace the normalized and ratioed clocks in the logical model of the circuit with a base system clock, divider logic generating hold waveforms to achieve ratioed behavior, and pulse-enabled latches, and replace the edge-triggered latches or flip-flops with pulse-generation logic and pulse-enabled latches,
execute a formal verification which determines whether the logical model of the circuit is functionally equivalent to the physical model of the circuit, and
display results of the formal verification via a graphical user interface (GUI) of the software application.

2. The apparatus of claim 1, wherein the logical model uses latches that update on both rising and falling edges of the normalized and ratioed clocks, and the physical model generates pulses on both rising and falling edges of the base system clock as controlled by a pair of hold waveforms.

3. The apparatus of claim 1, wherein the logical model uses latches that update on both rising and falling edges of the normalized and ratioed clocks with ratio N, and the physical model generates pulses on only a single edge of the base system clock as controlled by a hold waveform of reduced ratio N divided by 2.

4. The apparatus of claim 1, wherein at least one processor is configured to execute a simulation of the logical model and implement a fifty percent duty cycle model for the normalized and ratioed clocks during the simulation.

5. The apparatus of claim 1, wherein the logical model utilizes logic that counts edges of an input clock waveform exhibiting fifty percent duty cycle to produce an output waveform with fifty percent duty cycle but a longer period determined by an integer input ratio.

6. The apparatus of claim 1, wherein the logical model utilizes logic that detects edges of a base reference clock waveform occurring during active and inactive states of a normalized and ratioed clock waveform with fifty percent duty cycle, incrementing and decrementing a counter to predict subsequent edges of an input ratioed clock waveform, along with logic to produce a hold waveform.

7. The apparatus of claim 1, wherein the logical model specifies normalized clocks with an unspecified ratio and the physical model specifies hold signals with a corresponding unspecified ratio.

8. The apparatus of claim 1, wherein at least one processor is configured to create a composite model including both the logical model and the physical model and perform formal property checking analysis on the composite model to determine functional equivalence.

9. The apparatus of claim 8, wherein at least one processor is configured to identify inputs of the normalized and ratioed clocks within the composite model of the circuit and drive the inputs of the normalized and ratioed clocks to waveforms representing ratios of the normalized and ratioed clocks.

10. The apparatus of claim 8, wherein at least one processor is configured to add gating logic to the composite model to suppress spurious detection of irrelevant functional non-equivalence of hold waveforms in the physical model against hold waveforms in the logical model that occur while the base system clock is stable.

11. The apparatus of claim 8, wherein at least one processor is configured to add logic to the composite model to drive normalized clocks with unspecified ratio using a non-deterministic selection of one of several valid normalized and ratioed clock waveforms, and add additional logic to the composite model to translate a selected clock waveform into an equivalent hold waveform which is used to drive hold signals with corresponding unspecified ratio.

12. The apparatus of claim 8, wherein at least one processor is configured to add logic to the composite model to derive an expected waveform for a hold signal with unspecified ratio by transforming the expected waveform of a normalized clock signal with corresponding unspecified ratio and validate a function of the hold signal based on the expected waveform.

13. A method comprising:
receiving a logical model of a circuit written in a hardware description language (HDL), the logical model of the circuit comprising normalized and ratioed clocks, and simulation-efficient edge-triggered latches or flip-flops;
translating the logical model of the circuit into a physical model of the circuit in the HDL via a software application, wherein the translating comprises replacing the normalized and ratioed clocks in the logical model of the circuit with a base system clock, divider logic generating hold waveforms to achieve ratioed behavior, and pulse-enabled latches, and replacing the edge-triggered latches or flip-flops with pulse-generation logic and pulse-enabled latches;
executing a formal verification which determines whether the logical model of the circuit is functionally equivalent to the physical model of the circuit; and
displaying results of the formal verification via a graphical user interface (GUI) of the software application.

14. The method of claim 13, comprising executing a simulation of the logical model and implementing a fifty percent duty cycle model for the normalized and ratioed clocks during the simulation.

15. The method of claim 13, comprising creating a composite model including both the logical model and the physical model, and performing formal property checking analysis on the composite model to determine functional equivalence.

16. The method of claim 15, comprising identifying inputs of the normalized and ratioed clocks within the composite model of the circuit and driving the inputs of the normalized and ratioed clocks to waveforms representing ratios of the normalized and ratioed clocks.

17. The method of claim 15, comprising adding gating logic to the composite model to suppress spurious detection of irrelevant functional non-equivalence of hold waveforms in the physical model against hold waveforms in the logical model that occur while the base system clock is stable.

18. The method of claim 15, comprising adding logic to the composite model to drive normalized clocks with unspecified ratio using a non-deterministic selection of one of several valid normalized and ratioed clock waveforms, and adding additional logic to the composite model to translate a selected clock waveform into an equivalent hold waveform which is used to drive hold signals with corresponding unspecified ratio.

19. The method of claim 15, comprising adding logic to the composite model to derive an expected waveform for a hold signal with unspecified ratio by transforming the expected waveform of a normalized clock signal with corresponding unspecified ratio, and validating a function of the hold signal based on the expected waveform.

20. A computer-readable hardware storage medium comprising instructions which when executed by a processor cause the processor to perform:
receiving a logical model of a circuit written in a hardware description language (HDL), the logical model of the circuit comprising normalized and ratioed clocks, and simulation-efficient edge-triggered latches or flip-flops;
translating the logical model of the circuit into a physical model of the circuit in the HDL via a software application, wherein the translating comprises replacing the normalized and ratioed clocks in the logical model of the circuit with a base system clock, divider logic generating hold waveforms to achieve ratioed behavior, and pulse-enabled latches, and replacing the edge-triggered latches or flip-flops with pulse-generation logic and pulse-enabled latches;
executing a formal verification which determines whether the logical model of the circuit is functionally equivalent to the physical model of the circuit; and
displaying results of the formal verification via a graphical user interface (GUI) of the software application.
